(19) United States
(12) Patent Application Publication
(10) Pub. No.: US 2006/0091393 A1
(43) Pub. Date: May 4, 2006

(54) Isotopically pure silicon-on-insulator wafers and methods of making same

(76) Inventor: Stephen J. Burden, Golden, CO (US)

Correspondence Address: SHERIDAN ROSS PC, 1560 BROADWAY, SUITE 1200, DENVER, CO, 80202, US

(21) Appl. No.: 11/298,440

(22) Filed: Dec. 9, 2005

Related U.S. Application Data
(62) Division of application No. 10/746,426, filed on Dec. 24, 2003.
Application No. 10/746,426 is a continuation-in-part of application No. 10/189,732, filed on Jul. 3, 2002, now Pat. No. 6,867,459.
(60) Provisional application No. 60/303,455, filed on Jul. 5, 2001.

(51) Int. Cl. H01L 29/02

(52) U.S. Cl. 257/65; 257/347

(57) ABSTRACT

A semiconductor wafer structure having a device layer, an insulating layer, a semiconductor material layer and a substrate which is capable of supporting increased semiconductor device densities or increased semiconductor device power. One or more of the layers includes an isotopically enriched semiconductor material having a higher thermal conductivity than semiconductor material having naturally occurring isotopic ratios. The insulating layer may be formed by implanting atoms or ions into a semiconductor layer and subjecting the wafer to heat treatment resulting in the implanted atoms or ions reacting with the semiconductor layer to form an insulating layer.

### CROSS-REFERENCE TO RELATED APPLICATIONS

This application is a divisional of U.S. patent application Ser. No. 10/746,426, filed Dec. 24, 2003, which is a continuation-in-part of pending U.S. patent application Ser. No. 10/189,732 filed Jul. 3, 2002, which claims the benefit of U.S. Provisional Application No. 60/303,455 filed Jul. 5, 2001. These related applications are incorporated herein, in their entirety, by this reference.

### FIELD OF THE INVENTION

The present invention relates to methods of making improved semiconductor wafer structures having isotopically-enriched layers.

### BACKGROUND OF THE INVENTION

Silicon on insulator (SOI) wafers are becoming an increasingly accepted form of silicon wafer for the manufacture of semiconductor devices. SOI wafers have a thin layer of silicon dioxide below the surface of the single crystal silicon wafer. This layer electrically isolates the surface layer from the bulk of the wafer and allows semiconductor devices to operate at higher speeds with lower power consumption. Thus, the wafer structure consists of a top single crystal silicon layer (the device layer), an amorphous silicon dioxide layer (the buried oxide or BOX layer), and a substrate or handle wafer. The handle wafer is typically a single crystal silicon wafer. A typical wafer structure is shown in FIG. 1 in which layer 1 is the device layer wherein the semiconductor device is fabricated; layer 2 is the BOX or insulator layer; and layer 3 is the substrate.

Power dissipation in a semiconductor device is limited by the thermal conductivity of the materials from which it is made. This thermal conductivity in turn limits the packing density of the transistors on a semiconductor wafer or the amount of power that can be generated in a circuit without inducing circuit failure. Thus, one side effect of electrically isolating the top silicon layer with silicon dioxide is that the top layer is also thermally insulated from the silicon substrate. This accentuates the self-heating of circuits and can cause problems with high power devices such as microprocessors. Several designs have been proposed to overcome the detrimental effects of this thermal isolation including the use of local thermal paths to transport the heat through the oxide layer or the fabrication of a “partial” SOI wafer having areas of wafer without an oxide layer.

These designs are difficult and therefore expensive to implement. A novel solution provided by embodiments of the present invention is the use of high thermal conductivity silicon-28 in the manufacture of SOI wafers. By utilizing an isotopically-enriched silicon-28 device layer and/or an isotopically-enriched silicon-28 layer under the oxide, lateral heat spreading can be maximized. This is particularly true for thin-film SOI wafers where the top silicon layer is much less than one micron thick. With these wafers, the device layer can be natural silicon since the thermal transport in the device layer is controlled by interface scattering effects and not by the bulk properties of the silicon. In this case, an underlayer of isotopically-enriched silicon helps greatly to spread the heat generated in the device layer. Silicon-28 can be incorporated without changing the device design and at relatively modest cost since the amount of silicon-28 in these thin layers is small. Fabricating isotopically modified SOI wafers allows for increased power densities in these devices, thereby enhancing the performance of many electronic devices now on the market.

### SUMMARY OF THE INVENTION

Accordingly, the present invention provides improved semiconductor wafer structures having isotopically-enriched layers and methods of making such wafers. In one embodiment, a SOI wafer structure is provided wherein at least one of the layers includes an isotopically enriched material.

In one embodiment, the top device layer is an isotopically-enriched semiconductor material of isotopically-enriched silicon, isotopically-enriched germanium, isotopically-enriched silicon-germanium alloys and combinations and alloys thereof. The electrically-insulating layer is silicon dioxide or silicon nitride.

In another embodiment of the present invention, the wafer structure is comprised of an upper device layer comprised of an isotopically-enriched semiconductor layer, an insulating layer of silicon dioxide or silicon nitride, an isotopically enriched silicon substrate, or alternatively, an isotopically-enriched semiconductor layer which has been deposited on top of a natural silicon substrate.

### BRIEF DESCRIPTION OF THE DRAWINGS

FIG. 1 is a schematic of the typical prior art wafer structure in which layer 1 is the top silicon layer or device layer, layer 2 is the BOX or insulating layer and layer 3 is the natural silicon substrate. All the layers are composed of the normal isotopic ratios for the elements involved.

FIG. 2 is a schematic of one wafer structure of the present invention in which Layer 4 is a top isotopically enriched semiconductor layer or device layer, layer 5 is an isotopically enriched buried oxide or insulating layer; and layer 6 is a natural silicon substrate.

FIG. 3 is a schematic of another wafer structure of the present invention in which Layer 7 is the top isotopically enriched device layer, layer 8 is the buried oxide or insulator layer; layer 9 is a second isotopically-enriched semiconductor layer and layer 10 is the silicon substrate.

FIG. 4 depicts one manufacturing method of the present invention.

FIG. 5 illustrates a final wafer structure following the manufacturing method depicted in FIG. 4.

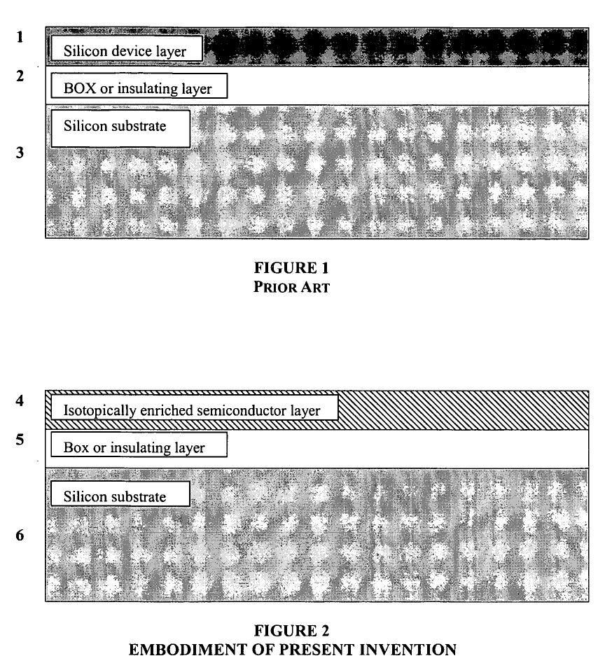

### DETAILED DESCRIPTION OF THE INVENTION

In the naturally occurring form, silicon is composed of three stable isotopes; approximately 92.2% ²⁸Si, 4.7% ²⁹Si and 3.1% ³⁰Si, which is roughly the composition of crystals and wafers used by the semiconductor industry. The presence of multiple isotopes contributes to phonon scattering which decreases the thermal conductivity of naturally occurring silicon.

Isotopically-enriched ²⁸Si has been shown to have a thermal conductivity 60% to 600% higher than naturally occurring silicon as described in Capinski et al., Thermal Conductivity of isotopically-enriched Si, Applied Physics Letters, v 71, pp. 2109-11 (1997), and Ruf et al., Thermal Conductivity of isotopically-enriched Silicon, Solid State Communications, v 115, pp. 243-47 (2000), both of which are incorporated herein in their entirety by this reference. Isotopically-enriched means the silicon has a higher proportion of one of the isotopes of silicon than is present in naturally occurring silicon (e.g., it is composed of at least 98% ²⁸Si).

Isotopically pure germanium has also demonstrated improved thermal conductivity over naturally occurring germanium crystals as described in Ozhogin et al, Isotope Effects in the Thermal Conductivity of Germanium Single Crystals, JETP Letters, Vol. 63, No. 6, pp 490-494, (1996), and in Asen-Palmer et al, Thermal Conductivity of Germanium Crystals with different Isotopic Compositions, Physical Review B, Vol. 56, No. 15, pp 9431-9447, (1997) incorporated herein in its entirety by this reference. In the case of germanium, isotopically-enriched means the enriched germanium has a higher proportion of one of the isotopes of Ge than is present in naturally occurring germanium (e.g., it is composed of at least 80% ⁷⁴Ge).

Higher thermal conductivity means devices fabricated from the high thermal conductivity wafer exhibit lower peak temperatures, faster device speeds and higher frequency performance than previous, conventional wafers. Lower temperatures will result in higher carrier mobility and reduced leakage currents which result in lower heat generation within the material. In addition, higher thermal conductivity means that it is possible to increase device packing densities within integrated circuit chip designs and to increase power output per unit area of power devices. Furthermore, the invention has applicability in device structures such as semiconductor laser arrays, micro-electromechanical devices (MEMS), micro-opto-electromechanical devices (MOEMS), optical switches, light emitting diodes, and laser diodes which utilize silicon substrates or silicon layers primarily for heat dissipation. The use of the present invention in such cases improves the thermal performance of the devices.

Any electronic device which relies on silicon, germanium, or Si—Ge alloys can be enhanced by the use of components made from the enriched isotopes to the extent that they impart improved thermal conductivity. Examples of such devices include integrated circuits, lasers, and diodes as described in U.S. Pat. No. 5,144,409 which is incorporated herein in its entirety by this reference.

Referring now to FIG. 2, a schematic of a wafer structure of an embodiment of the present invention is illustrated. In this embodiment, a top isotopically enriched semiconductor layer or device layer 4 is located on an isotopically enriched buried oxide or insulating layer 5. A natural silicon substrate 6 is located at the bottom layer, and in this embodiment is a silicon layer having naturally occurring isotopic ratios.

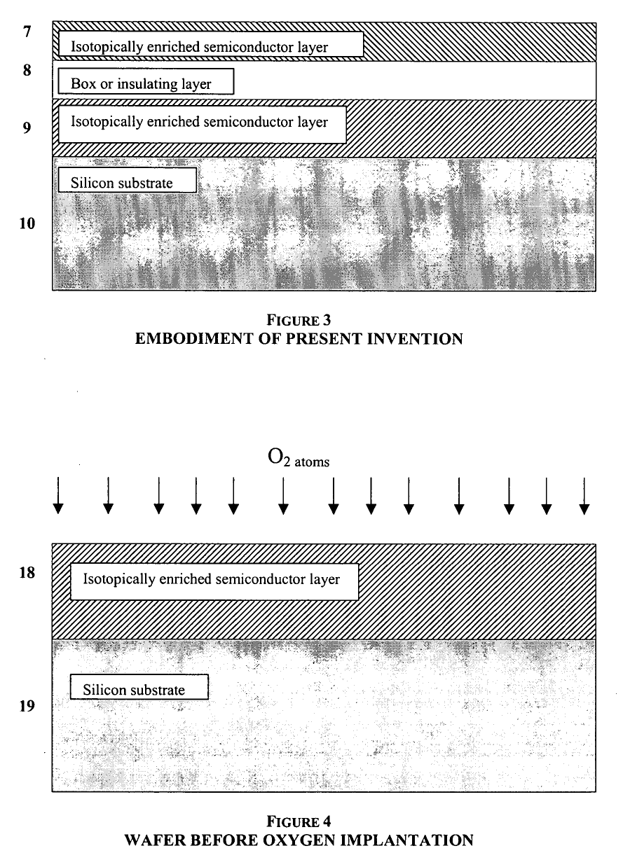

FIG. 3 is an illustration of a wafer structure of another embodiment of the present invention. In this embodiment, a top isotopically enriched device layer 7 is located on a buried oxide or insulator layer 8. A second isotopically-enriched semiconductor layer 9 is beneath the buried oxide 8, and layer 10 is the silicon substrate.

One embodiment of the present invention is a wafer structure formed by implanting oxygen or nitrogen atoms or ions beneath the surface of an isotopically enriched semiconductor substrate, or an isotopically enriched layer deposited on the surface of a suitable substrate. Such a fabrication method for the wafer structure is termed SIMOX (Separation by IMplantation of OXygen) processing, as described in U.S. Pat. Nos. 5,196,355, or 6,593,173. An electrically insulating layer is formed by heating the implanted wafer in an atmosphere of oxygen or nitrogen, or inert gas containing oxygen or nitrogen in suitable amounts. During the thermal treatment, the implanted oxygen or nitrogen atoms react with silicon to form silicon oxide or silicon nitride molecules which then coalesce into a sub-surface continuous film. The thickness of the insulating layer depends on the amount of oxygen or nitrogen implanted, the length of time the wafer is treated at an elevated temperature, and the amount of oxygen or nitrogen in the atmosphere during the elevated temperature treatment. The top enriched semiconductor layer thickness depends on the energy of the implanted atoms and can be from 1 to 10,000 angstroms (1 micron) thick, depending on the final use of the wafer.

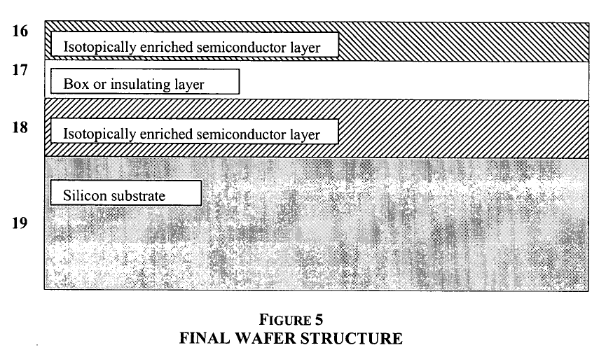

FIG. 4 depicts one manufacturing method of the present invention. A single crystal silicon substrate with an isotopically enriched semiconductor material layer 18, formed on a silicon substrate 19, is bombarded with oxygen atoms or ions with sufficient energy for the oxygen atoms to become lodged below the surface of the semiconductor layer. After a suitable heat treatment, the oxygen atoms coalesce into a continuous layer of silicon dioxide, forming the buried oxide layer. The heat treatment may be one of a number of suitable heat treatments, such as, for example, annealing by rapid thermal processing. The final wafer structure of this embodiment is illustrated in FIG. 5, which is identical to the wafer structure shown in FIG. 3.

The isotopically-enriched semiconductor layer can be composed of isotopically-enriched silicon, isotopically-enriched germanium, isotopically-enriched silicon-germanium alloys or combinations thereof. The isotopically-enriched layer serves to provide increased heat dissipation. The isotopically enriched layer can be formed by vapor phase epitaxial deposition or other technique used in the manufacture of epitaxial wafers.

In a preferred embodiment of the present invention, the isotopically enriched semiconductor layer is composed of at least 95%, more preferable at least 98%, and most preferably 99% of the silicon-28 isotope.

In another preferred embodiment of the present invention the isotopically enriched semiconductor layer is composed of at least 80% of one of the germanium isotopes.

In another preferred embodiment of the present invention the isotopically enriched semiconductor layer is composed of a silicon-germanium alloy wherein the silicon is enriched to at least 95%, more preferably 98%, and most preferably greater than 99% of the silicon-28 isotope.

In one preferred embodiment of the present invention, an epitaxial layer of silicon enriched to 99.9% of the silicon-28 isotope is grown on a single crystal silicon wafer which is composed of the natural isotopic ratio. The top surface of this epitaxial wafer is bombarded with oxygen atoms with an energy and dose sufficient to cause a buried oxide layer to form after annealing, of from 50 to 1000 angstroms thick at a depth of from 50 to 1000 angstroms beneath the surface.

The foregoing discussion of the invention has been presented for purposes of illustration and description. Further, the description is not intended to limit the invention to the form disclosed herein. Consequently, variations and modifications commensurate with the above teachings, within the skill and knowledge of the relevant art, are within the scope of the present invention. The embodiments described hereinabove are further intended to explain the best modes presently known of practicing the inventions and to enable others skilled in the art to utilize the inventions in such, or in other embodiments, and with the various modifications required by their particular application or uses of the invention. It is intended that the appended claims be construed to include alternative embodiments to the extent permitted by the prior art.

What is claimed is:

1. A multi-layer semiconductor wafer structure comprising:
a substrate;
an isotopically enriched semiconductor material layer;
an insulating layer; and,
a device layer of semiconducting material,
wherein said isotopically enriched semiconductor material layer comprises at least one of the isotopically enriched elements silicon, germanium, and silicon-germanium alloys.

2. The wafer structure of claim 1, wherein the isotopically enriched semiconductor material layer comprises a semiconductor material selected from the group consisting of silicon enriched to at least 95% of the silicon-28 isotope, germanium enriched to at least 80% of one of the germanium isotopes, silicon-germanium alloys enriched to at least 95% of the silicon-28 isotope, and combinations and alloys thereof.

3. The wafer structure of claim 1, wherein the isotopically enriched semiconductor material layer comprises multiple layers of semiconductor material selected from the group consisting of silicon enriched to at least 95% of the silicon-28 isotope, germanium enriched to at least 80% of one of the germanium isotopes, silicon-germanium alloys enriched to at least 95% of the silicon-28 isotope, and combinations and alloys thereof.

4. The wafer structure of claim 1, wherein the isotopically enriched semiconductor material layer is formed by a method selected from the group consisting of chemical vapor deposition, molecular beam epitaxy, vapor phase epitaxy, liquid phase epitaxy, atomic layer deposition or physical vapor deposition.

5. The wafer structure of claim 1, wherein the isotopically enriched semiconductor material layer and the device layer are both isotopically enriched semiconductor material layers having the same elemental composition.

6. The wafer structure of claim 1, wherein the device layer comprises a semiconductor material selected from the group consisting of silicon enriched to at least 95% of the silicon-28 isotope, germanium enriched to at least 80% of one of the germanium isotopes, silicon-germanium alloys enriched to at least 95% of the silicon-28 isotope, and combinations and alloys thereof.

7. The wafer structure of claim 1, wherein the insulating layer is formed by implantation of oxygen or nitrogen atoms or ions into an isotopically enriched semiconductor layer.

8. The wafer structure of claim 1, wherein the insulating layer is silicon dioxide or silicon nitride.

9. The wafer structure of claim 1, wherein the substrate comprises silicon with natural isotopic ratios and the semiconductor material layer comprises silicon with at least 95% of the silicon-28 isotope.

10. The wafer structure of claim 1, wherein the substrate comprises silicon with natural isotopic ratios and the semiconductor material layer comprises silicon with at least 98% of the silicon-28 isotope.

11. The wafer structure of claim 1, wherein the substrate comprises silicon with natural isotopic ratios and the semiconductor material layer comprises silicon with at least 99% of the silicon-28 isotope.

12. The wafer structure of claim 1, wherein the substrate comprises a semiconductor material selected from the group consisting of silicon, germanium, silicon-germanium alloys, and combinations and alloys thereof.

13. The wafer structure of claim 1, wherein the substrate comprises a semiconductor material selected from the group consisting of silicon enriched to at least 95% of the silicon-28 isotope, germanium enriched to at least 80% of one of the germanium isotopes, silicon-germanium alloys enriched to at least 95% of the silicon-28 isotope, and combinations and alloys thereof.

14. The wafer structure of claim 1, wherein the substrate comprises silicon of natural isotopic ratios, the isotopically enriched semiconductor layer is composed of at least 98% of the silicon-28 isotope, the electrically insulating layer is formed by thermal oxidation of the isotopically enriched silicon-28 layer, and the device layer comprises one or more layers of silicon enriched to at least 95% of the silicon-28 isotope, germanium enriched to at least 80% of one of the germanium isotopes, or silicon-germanium alloys enriched to at least 95% of the silicon-28 isotope.

15. The wafer structure of claim 1, wherein the substrate comprises silicon of natural isotopic ratios, the isotopically enriched semiconductor layer is composed of at least 98% of the silicon-28 isotope, the electrically insulating layer is formed by thermal oxidation of the isotopically enriched silicon-28 layer, and the device layer comprises at least one layer of silicon, germanium, and silicon-germanium alloys.
